(19) United States
(12) Patent Application Publication
(10) Pub. No.: US 2025/0247998 A1
(43) Pub. Date: Jul. 31, 2025

(54) Thermal Energy Transfer Assembly And Method Of Making The Same

(71) Applicant: BorgWarner Inc., Auburn Hills, MI (US)

(72) Inventor: Kurt F. O'Connor, Carmel, IN (US)

(21) Appl. No.: 18/426,054

(22) Filed: Jan. 29, 2024

(51) Int. Cl. H05K 7/20; B23K 20/12; B23K 101/42

(52) U.S. Cl. CPC H05K 7/20254; B23K 20/122; B23K 20/129; H05K 7/20009; B23K 2101/42

(57) ABSTRACT

A thermal energy transfer assembly includes a substrate made of a first material which has a first thermal conductivity coefficient, the substrate having a first surface and a second surface which is opposed to the first surface. The thermal energy transfer assembly also includes a thermal energy transfer element made of a second material having a second thermal conductivity coefficient which is greater than the first thermal conductivity coefficient. The thermal energy transfer element is applied to the first surface using additive friction stir deposition and extends into the substrate toward the second surface. The thermal energy transfer element and the substrate meet together in a stir zone which includes a mixture of both the first material and the second material.

### TECHNICAL FIELD OF INVENTION

The present disclosure relates to a thermal energy transfer assembly and more particularly to a thermal energy transfer assembly which includes one or more thermal energy transfer elements. The present disclosure also relates to a method of making the thermal energy transfer assembly and more particularly to a method which includes using additive friction stir deposition to apply the thermal energy transfer element to a substrate.

### BACKGROUND OF INVENTION

Thermal energy transfer assemblies such as heat sinks and cold plates are well known for transferring thermal energy to or from devices such as electric motors, electronic devices, and batteries as well as media such as liquids or gases. Such thermal energy transfer assemblies often employ one or more fins which extend outward from a base such that the fins provide a large surface area in order to maximize thermal energy transfer. The base is typically in direct contact with the device with which thermal energy is to be transferred and the one or more fins are in contact with a fluid, either a liquid or a gas, which provides the heating or cooling capacity. The fins of the thermal energy transfer assembly are often formed by machining material away from a blank, by net forming through casting or extrusion, or by fastening separately formed fins to the base by way of resistance welding, brazing, soldering, interference fit, or mechanical fasteners.

While numerous thermal energy transfer assemblies are known in the art, improvements in efficiency, space utilization, ease of manufacture, and cost are continually desired.

### SUMMARY OF THE INVENTION

Briefly described, the present disclosure provides a method for forming a thermal energy transfer assembly through which thermal energy is transferred. The method includes providing a substrate made of a first material which has a first thermal conductivity coefficient, the substrate having a first surface and a second surface which is opposed to the first surface. The method also includes applying a thermal energy transfer element, made of a second material having a second thermal conductivity coefficient which is greater than the first thermal conductivity coefficient, to the substrate from the first surface using additive friction stir deposition, such that the thermal energy transfer element extends into the substrate toward the second surface, wherein the thermal energy transfer element and the substrate meet together in a stir zone which comprises a mixture of both the first material and the second material.

The present disclosure also provides a thermal energy transfer assembly through which thermal energy is transferred. The thermal energy transfer assembly includes a substrate made of a first material which has a first thermal conductivity coefficient, the substrate having a first surface and a second surface which is opposed to the first surface. The thermal energy transfer assembly also includes a thermal energy transfer element made of a second material having a second thermal conductivity coefficient which is greater than the first thermal conductivity coefficient, the thermal energy transfer element is applied to the first surface using additive friction stir deposition and extends into the substrate toward the second surface, wherein the thermal energy transfer element and the substrate meet together in a stir zone which comprises a mixture of both the first material and the second material.

The thermal energy transfer assembly and the method for forming a thermal energy transfer assembly as disclosed herein provide for ease of manufacturing economically while also providing high performance in transferring thermal energy.

### BRIEF DESCRIPTION OF DRAWINGS

This invention will be further described with reference to the accompanying drawings in which:

FIG. 1 is an isometric view showing a simplified representation of a thermal energy transfer assembly in accordance with the present disclosure;

FIG. 2 is an enlarged cross-sectional view of a portion of FIG. 1 taken through section line 2-2 of FIG. 1;

FIG. 3 is an isometric view showing an additive friction stir deposition process which is used for applying a thermal energy transfer element to a substrate in the thermal energy transfer assembly;

FIG. 4 is a cross-sectional view of a simplified representation of a thermal energy transfer assembly in accordance with the present disclosure;

FIG. 5 is an elevation view of a simplified representation of a thermal energy transfer assembly in accordance with the present disclosure;

FIG. 6 is a cross-sectional view taken through section line 6-6 of FIG. 5 and including a printed circuit board assembly;

FIG. 7 is a cross-sectional view of a simplified representation of a portion of a turbocharger in accordance with the present disclosure;

FIG. 8 is a radial cross-sectional view taken through section line 8-8 of FIG. 7;

FIG. 9 is an elevation view of a simplified representation of a thermal energy transfer assembly in accordance with the present disclosure; and

FIG. 10 is an enlarged cross-sectional view of a portion of FIG. 9 taken through section line 10-10 of FIG. 9.

### DETAILED DESCRIPTION OF INVENTION

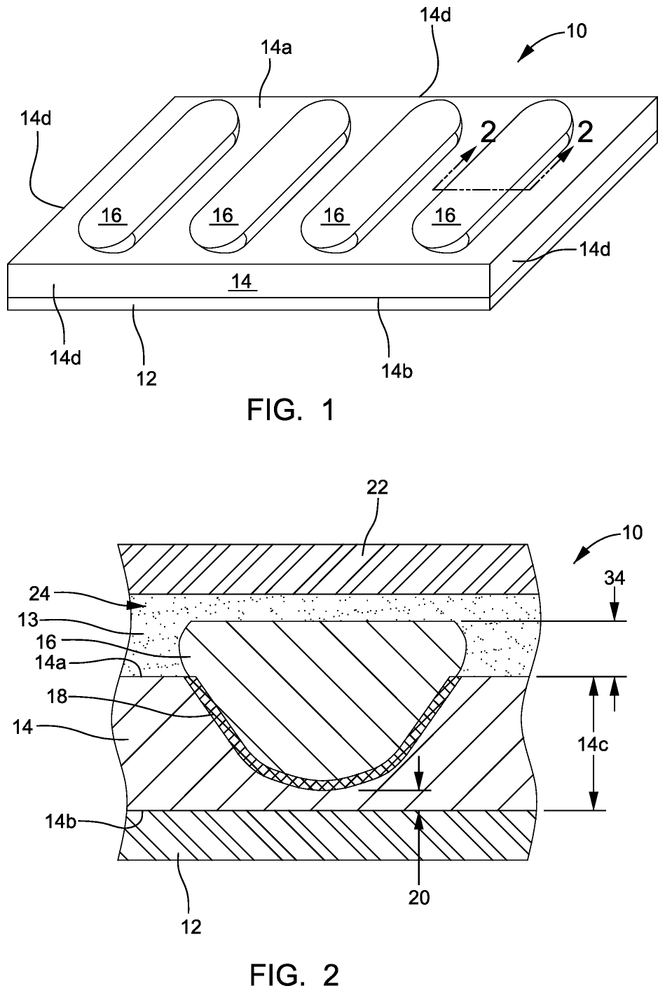

Initial reference will be made to FIGS. 1 and 2 where FIG. 1 is an isometric view showing a simplified representation of a thermal energy transfer assembly 10 and FIG. 2 is an enlarged cross-sectional view of a portion of thermal energy transfer assembly 10 taken through section line 2-2 of FIG. 1. Thermal energy transfer assembly 10 is provided for transferring thermal energy between matter 12 and a fluid 13. In other words, thermal energy transfer assembly 10 provides thermal energy to matter 12 or extracts thermal energy from matter 12 based on a thermal energy differential between matter 12 and fluid 13. Matter 12 may be, by way of non-limiting example only, a device such as an electric motor, a battery such as a battery pack for an electric vehicle, an electronic device such as a power inverter, power converter, power transistor, thyristor, diode, integrated circuit, CPU processor, microprocessor, power handling semiconductor, LED, and the like, or a turbocharger for an internal combustion. In one or more of these exemplary devices, the device may either be cooled or heated using thermal energy transfer assembly 10 or may be both heated and cooled using thermal energy transfer assembly 10 depending on operational needs of the device. For example, when the device is as a battery or battery pack for an electric vehicle, thermal energy transfer assembly 10 may be used to provide heat to the battery or battery pack under some operating conditions such as when the electric vehicle is in a standby mode. Conversely, thermal energy transfer assembly 10 may be used to provide cooling to the battery or battery pack when the battery or battery pack is being discharged to provide propulsion to the electric vehicle. Alternatively, matter 12 may be a fluid, e.g. a liquid or a gas, to which thermal energy is to be provided or from which thermal energy is to be extracted. Fluid 13 may be a liquid, gas, or phase change material and may be contained within a closed system containing, by way of nonlimiting example only, water or a mixture of water and an antifreeze such as ethylene glycol or propylene glycol which is recirculated or may be an open system such as atmospheric air or water which is not recirculated. Thermal energy transfer assembly 10 includes a substrate 14 which is made of a first material having a first thermal conductivity coefficient. Substrate 14 has a first surface 14a, a second surface 14b which is opposed to first surface 14a, and a thickness 14c which is a measure of substrate 14 between first surface 14a and second surface 14b in a direction normal to second surface 14b. Second surface 14b is in thermal conduction with matter 12 by either direct contact or through an intermediate element such as a thermal pad or thermal paste (not shown). By way of non-limiting example only, substrate 14 is made of aluminum or an aluminum alloy. While aluminum and aluminum alloy have been given as examples of the material for substrate 14, it should be understood that other metals may also be used where the metals may be ferrous or non-ferrous. It should also be understood that the material for substrate 14 may alternatively not be a metal, but may be a polymer.

In order to promote transfer of thermal energy between matter 12 and fluid 13 through substrate 14, thermal energy transfer assembly 10 also includes one or more thermal energy transfer elements 16 which are made of a second material which is different from the first material of substrate 14 such that the second material has a second thermal conductivity coefficient which is greater than the first thermal conductivity coefficient of the first material of substrate 14. Preferably, the second thermal conductivity coefficient measured in watts per meter Kelvin (W/mK) is at least 1.5 times the first thermal conductivity coefficient measured in W/mK in order to promote effective thermal energy transfer. By way of non-limiting example only, thermal energy transfer element 16 is made of copper or a copper alloy, however, other materials where the second thermal conductivity coefficient is at least 1.5 times the first thermal conductivity coefficient are also possible. One non-limiting example of a non-metal option for thermal energy transfer elements 16 is graphene, however, other non-metal options may include composite materials. Additionally, thermal energy transfer element 16 may be made of two or more compositions such as copper and silver or gold or alloys thereof. Thermal energy transfer elements 16 are applied to first surface 14a using additive friction stir deposition, as will be described in greater detail later, such that thermal energy transfer elements 16 extend into substrate 14 toward second surface 14b. Each thermal energy transfer element 16 and substrate 14 meet together in a stir zone 18 which comprises a mixture of both the first material of substrate 14 and the second material of thermal energy transfer element 16 as will be better understood later during the description of the additive friction deposition process which is used to apply thermal energy transfer element 16 to substrate 14. As shown most clearly in FIG. 2, each thermal energy transfer element 16 not only extends toward second surface 14b, but also extends away from first surface 14a in a direction that is opposite from second surface 14b, i.e. thermal energy transfer element 16 extends above first surface 14a as will be used hereinafter regardless of the orientation in the figures. However, it should be understood that each thermal energy transfer element 16 may alternatively not extend above first surface 14a, but rather may be flush with first surface 14a. When each thermal energy transfer element 16 extends away from first surface 14a in a direction that is opposite from second surface 14b, the surface area of each thermal energy transfer element 16 that is exposed to fluid 13 is increased, thereby improving thermal energy transfer efficiency. Additionally, each thermal energy transfer element 16 may promote turbulence to the flow of fluid 13 which may be beneficial to thermal energy transfer.

In order to maximize transfer of thermal energy between matter 12 and fluid 13 through substrate 14, it is desirable to minimize a distance 20 which extends from second surface 14b to the closest portion of thermal energy transfer element 16 including stir zone 18, in a direction normal to second surface 14b. When thickness 14c of substrate 14 is relatively small, for example, less than about 0.2 inches, distance 20 is less than 10% of thickness 14c and may be zero, e.g. thermal energy transfer element 16 including stir zone 18 may extend entirely through substrate 14 to second surface 14b. However, when thickness 14c is 0.2 inches or larger, distance 20 may be less than 50% of thickness 14c.

As illustrated in FIG. 2, thermal energy transfer assembly 10 may also include an enclosure 22 which is spaced apart from first surface 14a of substrate 14, thereby defining a fluid passage 24 between first surface 14a and enclosure 22 though which fluid 13 passes. It should be noted that enclosure 22 has been omitted from FIG. 1 in order to clearly view the plurality of thermal energy transfer elements 16. Consequently, in this arrangement, fluid 13 may be directed over first surface 14a and thermal energy transfer elements 16 in a controlled manner. While thermal energy transfer assembly 10 has been illustrated in FIG. 2 as including enclosure 22, it should be understood that enclosure 22 may alternatively be omitted, for example, in an arrangement where first surface 14a and thermal energy transfer elements 16 are exposed to atmospheric air.

As illustrated in FIG. 1, thermal energy transfer element 16 may be one of a plurality of thermal energy transfer elements 16 which are each substantially linear and discrete from each other. However, it should be understood that the plurality of thermal energy transfer elements 16 may alternatively be a single, continuous thermal energy transfer element where ends of adjacent parallel sections are joint together in an alternating manner, thereby forming a serpentine pattern. It is also contemplated that the thermal energy transfer element is not linear, but may take other forms to increase surface area, such as being sinusoidal, square wave or saw tooth in form, or may be made in other shapes or patterns which may include an array of thermal energy transfer elements where each thermal energy transfer element is a discrete point or post.

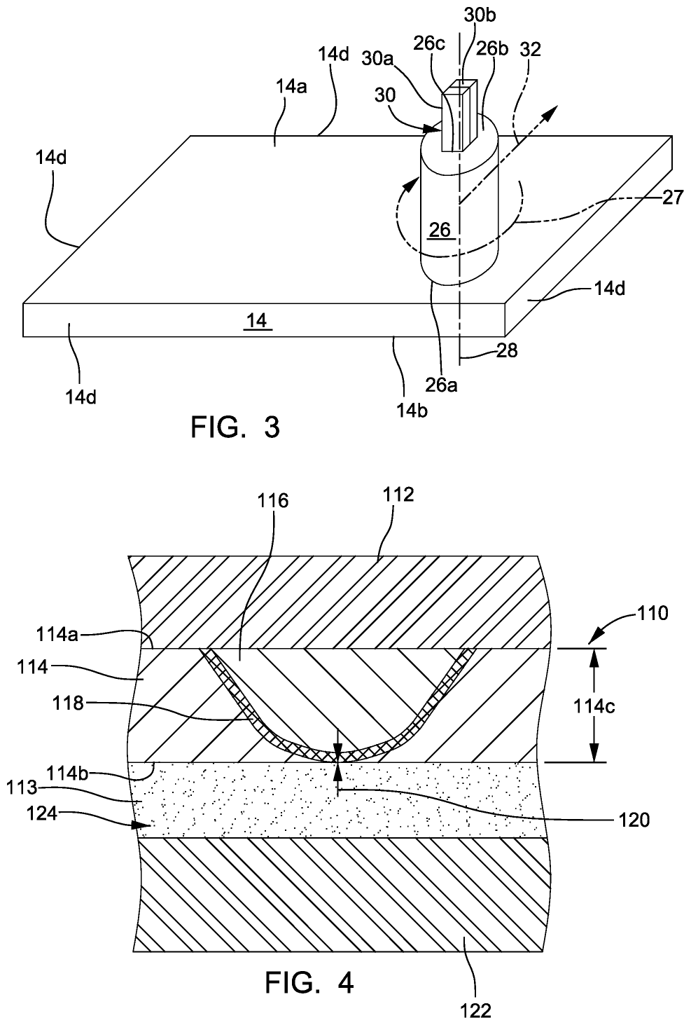

With continued reference to FIGS. 1 and 2 and now with additional reference to FIG. 3, an overview of the additive friction stir deposition process will now be described which is used to apply thermal energy transfer elements 16. While an overview of the additive friction stir deposition process is being provided herein, it should be understood that other details of the additive friction stir deposition process will be readily recognized and known by a practitioner of ordinary skill in the art. In order to apply thermal energy transfer elements 16 to substrate 14, a stir head 26 is provided which rotates about an axis 28, for example, by a motor (not shown) where rotation is indicated by rotation arrow 27. While rotation arrow 27 has been illustrated as being clockwise in FIG. 3, it should be understood that rotation of stir head 26 may alternatively be counterclockwise and the rotational direction of stir head 26 may change during the manufacture of thermal transfer assembly 10 depending on the characteristics desired for each thermal energy transfer element 16. Stir head 26 includes a first end 26a which is proximal to substrate 14 during the additive friction stir deposition process, a second end 26b which is distal from substrate 14 during the additive friction stir deposition process, and a bore 26c which is centered about axis 28 and which extends from first end 26a to second end 26b. Feedstock 30 is fed through bore 26c during the additive friction stir process and may take the form of bar stock or powder, however it is important to note that feedstock 30 is the second material of which thermal energy transfer element 16 is formed. In keeping with the non-limiting example provided earlier, feedstock 30 may be copper or copper alloy, however, other materials where the second thermal conductivity coefficient is at least 1.5 times the first thermal conductivity coefficient are also possible. Additionally, thermal energy transfer element 16 may be made of two or more compositions such as copper and silver or gold or alloys thereof.

In order to apply thermal energy transfer elements 16, stir head 26 is brought into contact with first surface 14a of substrate 14 while stir head 26 is rotated rapidly as indicated by rotation arrow 27. Bringing stir head 26 into contact with first surface 14a of substrate 14 may be accomplished by one or more of 1) translating stir head 26 toward substrate 14 and 2) translating substrate 14 toward stir head 26. Furthermore, stir head 26 may be plunged into first surface 14a of substrate 14 along axis 28 or stir head 26 may enter substrate 14 through an edge of 14d of substrate 14. The rotating nature of stir head 26 and bringing stir head 26 into contact with substrate 14 generates heat which causes plastic deformation of substrate 14, however, substrate 14 does not liquify. Simultaneously, feedstock 30 is forced through bore 26c and feedstock 30 is similarly caused to plastically deform without liquifying. Since substrate 14 and feedstock 30 are plastically deformed and are not liquified, a portion of substrate 14 and feedstock 30 is blended to form a mixture, thereby resulting in stir zone 18 while a portion of feedstock 30 is deposited, thereby forming thermal energy transfer element 16. Relative translation between substrate 14 and stir head 26 in a direction laterally relative to axis 28 as indicated by translation arrow 32 provides the elongated nature of thermal energy transfer element 16 across substrate 14. However, it should be understood that relative translation in multiple directions can be imparted to achieve other patterns that are not linear, for example, sinusoidal, square wave or saw tooth forms. Additionally, if substrate 14 is not planar, for example, substrate 14 may be cylindrical, the relative translation may be rotation of substrate 14. Each thermal energy transfer element 16 may be terminated by withdrawing stir head 26 and feedstock 30 from substrate 14, either in a direction along axis 28 or by exiting one edge 14d of substrate 14. Thermal energy transfer elements 16 may each be built in multiple layers, that is, by repeatedly providing relative translation between substrate 14 and stir head 26 in the direction laterally relative to axis 28 across the previous layer while adjusting the position between substrate 14 and stir head 26 along axis 28 to accommodate each subsequent layer. When multiple layers are used to form thermal energy transfer elements 16, each layer may be made from the same material as previous layers, however, it is contemplated that one or more layers of thermal energy transfer elements 16 may be made of a different material which may provide desired mechanical or thermal energy transfer characteristics to thermal energy transfer elements 16. In this way, thermal energy transfer elements 16 may each be formed to extend above first surface 14a by a height 34 in order to provide desired thermal energy transfer properties of thermal energy transfer elements 16.

While feedstock 30 has been illustrated as being square or rectangular in cross-sectional shape in a direction perpendicular to axis 28, it should be understood that feedstock 30 may alternatively be circular in cross-sectional shape or any other shape. Additionally, FIG. 3 shows feedstock 30 including a first composition 30a, for example copper or a copper alloy, and a second composition 30b, for example silver or gold or alloys thereof, however, it should be understood that feedstock 30 may include only one composition or may include more than two compositions. FIG. 3 illustrates both first composition 30a and second composition 30b being fed through bore 26c, however, it should be understood that first composition 30a and second composition 30b may each be fed through their own respective bores. Additionally, any one or more composition may be fed through a bore which is not centered about axis 28. One advantage of feedstock 30 including multiple compositions is that desired thermal and structural properties of thermal energy transfer element 16 can be achieved, however, if cost is a significant factor, a single composition may be used which minimizes or eliminates high-cost compositions.

Reference will now be made particularly to FIG. 4 which shows a cross-sectional view of a thermal energy transfer assembly 110 where the cross-sectional view of FIG. 4 is similar to that of FIG. 2. Thermal energy transfer assembly 110 is provided for transferring thermal energy between matter 112 and a fluid 113. In other words, thermal energy transfer assembly 110 provides thermal energy to matter 112 or extracts thermal energy from matter 112 based on a thermal energy differential between matter 112 and fluid 113. Matter 112 may be, by way of non-limiting example only, a device such as an electric motor, a battery such as a battery pack for an electric vehicle, an electronic device such as a power inverter, power converter, power transistor, thyristor, diode, integrated circuit, CPU processor, microprocessor, power handling semiconductor, LED, and the like, or a turbocharger for an internal combustion engine or a bearing of the turbocharger. Alternatively, matter 112 may be a fluid, e.g. a liquid or a gas, to which thermal energy is to be provided or from which thermal energy is to be extracted. Fluid 113 may be a liquid, gas, or phase change material and may be contained within a closed system containing, by way of nonlimiting example only, water or a mixture of water and an antifreeze such as ethylene glycol or propylene glycol which is recirculated or may be an open system such as atmospheric air or water which is not recirculated. Thermal energy transfer assembly 110 includes a substrate 114 which is made of a first material having a first thermal conductivity coefficient. Substrate 114 has a first surface 114a, a second surface 114b which is opposed to first surface 114a, and a thickness 114c which is a measure of substrate 114 between first surface 114a and second surface 114b in a direction normal to second surface 114b. First surface 114a is in thermal conduction with matter 12 by either direct contact or through an intermediate element such as a thermal pad or thermal paste (not shown). By way of non-limiting example only, substrate 114 is made of aluminum or an aluminum alloy. While aluminum and aluminum alloy have been given as examples of the material for substrate 114, it should be understood that other metals may also be used where the metals may be ferrous or non-ferrous. It should also be understood that the material for substrate 114 may alternatively not be a metal, but may be a polymer.

In order to promote transfer of thermal energy between matter 112 and fluid 113 through substrate 114, thermal energy transfer assembly 110 also includes one or more thermal energy transfer elements 116 which are made of a second material which is different from the first material of substrate 114 such that the second material has a second thermal conductivity coefficient which is greater than the first thermal conductivity coefficient of the first material of substrate 114. Preferably, the second thermal conductivity coefficient measured in W/mK is at least 1.5 times the first thermal conductivity coefficient measured in W/mK in order to promote effective thermal energy transfer. By way of non-limiting example only, thermal energy transfer element 116 is made of copper or a copper alloy, however, other materials where the second thermal conductivity coefficient is at least 1.5 times the first thermal conductivity coefficient are also possible. One non-limiting example of a non-metal option for thermal energy transfer element 116 is graphene, however, other non-metal options may include composite materials. Additionally, thermal energy transfer element 116 may be made of two or more compositions such as copper and silver or gold or alloys thereof. Thermal energy transfer element 116 is applied to first surface 114a using additive friction stir deposition, as was described previously, such that thermal energy transfer element 116 extends into substrate 114 toward second surface 114b. Thermal energy transfer element 116 and substrate 114 meet together in a stir zone 118 which comprises a mixture of both the first material of substrate 114 and the second material of thermal energy transfer element 116 as was described previously during the description of the additive friction deposition process. Unlike thermal energy transfer element 16 of thermal energy transfer assembly 10 which extends both toward second surface 14b and above first surface 14a, thermal energy transfer element 116 extends toward second surface 114b, however, does not extend above first surface 114a. In other words, thermal energy transfer element 116 may be flush with first surface 114a. This may be accomplished, by way of non-limiting example only, by net forming thermal energy transfer element 116 to be flush with first surface 114a or by first forming thermal energy transfer element 116 to extend above first surface 114a then using a material subtraction process such as machining or grinding to make thermal energy transfer element 116 flush with first surface 114a.

In order to maximize transfer of thermal energy between matter 112 and fluid 113 through substrate 114, it is desirable to minimize a distance 120 which extends from second surface 114b to the closest portion of thermal energy transfer element 116 including stir zone 118, in a direction normal to second surface 114b. When thickness 114c of substrate 114 is relatively small, for example, less than about 0.2 inches, distance 120 is less than 10% of thickness 114c and may be zero, e.g. thermal energy transfer element 116 including stir zone 118 may extend entirely through substrate 114 to second surface 114b. However, when thickness 114c is 0.2 inches or larger, distance 120 may be less than 50% of thickness 114c. As illustrated in FIG. 4, distance 120 is zero or near zero.

As illustrated in FIG. 4, thermal energy transfer assembly 110 may also include an enclosure 122 which is spaced apart from second surface 114b of substrate 114 in a direction opposite of first surface 114a, thereby defining a fluid passage 124 between second surface 114b and enclosure 122 though which fluid 113 passes. Consequently, in this arrangement, fluid 113 may be directed over second surface 114b and in close proximity to thermal energy transfer elements 116 in a controlled manner. While thermal energy transfer assembly 110 has been illustrated in FIG. 4 as including enclosure 122, it should be understood that enclosure 122 may alternatively be omitted, for example, in an arrangement where second surface 114b is exposed to atmospheric air.

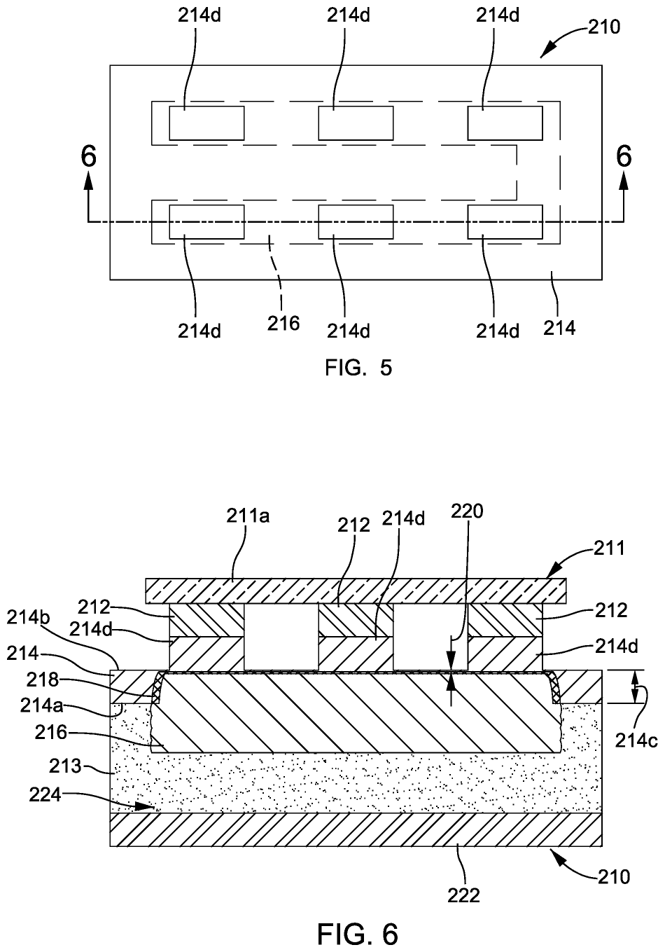

Reference will now be made to FIGS. 5 and 6 where FIG. 5 illustrates an elevation view of a thermal energy transfer assembly 210 and where FIG. 6 illustrates a cross-sectional view of the thermal energy transfer assembly 210 taken through section line 6-6 of FIG. 5 and including a printed circuit board assembly 211 which is positioned on thermal energy transfer assembly 210. Printed circuit board assembly 211 includes a printed circuit board 211a and one or more devices 212 which may require cooling during operation. Printed circuit board 211a includes a series of electrically conductive traces (not shown) which are used to communicate electricity between numerous electrical components which may be, by way of non-limiting example only, a power supply, resisters, capacitors, transformers, LEDs, diodes, transistors (all not shown), and devices 212. Devices 212 may each be, by way of non-limiting example only, a power inverter, power converter, power transistor, thyristor, diode, integrated circuit, CPU processor, microprocessor, power handling semiconductor, or any other electronic device which may generate heat during operation and which may need to be cooled to maintain desired operation and longevity. Thermal energy transfer assembly 210 is provided for transferring thermal energy between devices 212 and a fluid 213. In other words, thermal energy transfer assembly 210 extracts thermal energy from devices 212 based on a thermal energy differential between devices 212 and fluid 213. Fluid 213 may be a liquid, gas, or phase change material and may be contained within a closed system containing, by way of nonlimiting example only, water or a mixture of water and an antifreeze such as ethylene glycol or propylene glycol which is recirculated or may be an open system such as atmospheric air or water which is not recirculated. Thermal energy transfer assembly 210 includes a substrate 214 which is made of a first material having a first thermal conductivity coefficient. Substrate 214 has a first surface 214a, a second surface 214b which is opposed to first surface 214a, and a thickness 214c which is a measure of substrate 214 between first surface 214a and second surface 214b in a direction perpendicular to second surface 214b. Substrate 214 may also include one or more pedestals 214d which extend away from second surface 214b in a direction opposite from first surface 214a. Pedestals 214d are spaced about second surface 214b to correspond with the spacing of devices 212 about printed circuit board 211a. In this way, each device 212 is placed in thermal conduction with a respective one of pedestals 214d. It should be noted that a thermal pad or thermal paste may be placed between each device 212 and its respective pedestal 214d while providing thermal conduction between each device 212 and its respective pedestal 214d. By way of non-limiting example only, substrate 14 is made of aluminum or an aluminum alloy. While aluminum and aluminum alloy have been given as examples of the material for substrate 214, it should be understood that other metals may also be used where the metals may be ferrous or non-ferrous. It should also be understood that the material for substrate 214 may alternatively not be a metal, but may be a polymer.

In order to promote transfer of thermal energy between devices 212 and fluid 213 through substrate 214, thermal energy transfer assembly 210 also includes one or more thermal energy transfer elements 216 which are made of a second material which is different from the first material of substrate 214 such that the second material has a second thermal conductivity coefficient which is greater than the first thermal conductivity coefficient of the first material of substrate 214. Preferably, the second thermal conductivity coefficient measured in W/mK is at least 1.5 times the first thermal conductivity coefficient measured in W/mK in order to promote effective thermal energy transfer. By way of non-limiting example only, thermal energy transfer element 216 is made of copper or a copper alloy, however, other materials where the second thermal conductivity coefficient is at least 1.5 times the first thermal conductivity coefficient are also possible. One non-limiting example of a non-metal option for thermal energy transfer element 216 is graphene, however, other non-metal options may include composite materials. Additionally, thermal energy transfer element 216 may be made of two or more compositions such as copper and silver or gold or alloys thereof. As illustrated in the arrangement of FIGS. 5 and 6, a single thermal energy transfer element 216 is provided such that thermal energy transfer element is U-shaped (most easily observed in FIG. 5) and extends below each pedestal 214d. Thermal energy transfer element 216 is applied to first surface 214a using additive friction stir deposition as was described previously, such that thermal energy transfer element 216 extends into substrate 214 toward second surface 214b. Thermal energy transfer element 216 and substrate 214 meet together in a stir zone 218 which comprises a mixture of both the first material of substrate 214 and the second material of thermal energy transfer element 216 as was described previously during the description of the additive friction deposition process. As shown most clearly in FIG. 6, thermal energy transfer element 216 not only extends toward second surface 214b, but also extends above first surface 214a, i.e. thermal energy transfer element 216 extends beyond first surface 214a in a direction opposite from second surface 214b. However, it should be understood that thermal energy transfer element 216 may alternatively not extend above first surface 214a, but rather may be flush with first surface 214a. When each thermal energy transfer element 216 extends away from first surface 214a in a direction that is opposite from second surface 214b, the surface area of each thermal energy transfer element 216 that is exposed to fluid 213 is increased, thereby improving thermal energy transfer efficiency. Additionally, each thermal energy transfer element 216 may promote turbulence to the flow of fluid 213 which may be beneficial to thermal energy transfer.

In order to maximize transfer of thermal energy between devices 212 and fluid 213 through substrate 214, it is desirable to minimize a distance 220 which extends from second surface 214b to the closest portion of thermal energy transfer element 216 including stir zone 218, in a direction normal to second surface 214b. When thickness 214c of substrate 214 is relatively small, for example, less than about 0.2 inches, distance 20 is less than 10% of thickness 214c and may be zero, e.g. thermal energy transfer element 216 including stir zone 218 may extend entirely through substrate 214 to second surface 214b without extending into pedestals 214d which could compromise the integrity of pedestals 214d during the additive friction stir process. However, when thickness 214c is 0.2 inches or larger, distance 220 may be less than 50% of thickness 214c. It should be noted that thermal energy transfer element 16 has been drawn in FIG. 6 to emphasize that it has been created by building up multiple layers as is particularly evident by the scalloped lateral edges which are located outside of substrate 214, however, the absence of scalloping in thermal energy transfer elements in other figures and views does not indicate that the thermal energy transfer element was not created by building up multiple layers. In each instance the thermal energy transfer element may be formed by a single layer or any number of multiple layers.

As illustrated in FIG. 6, thermal energy transfer assembly 210 may also include an enclosure 222 which is spaced apart from first surface 214a of substrate 214, thereby defining a fluid passage 224 between first surface 214a and enclosure 222 though which fluid 213 passes. Consequently, in this arrangement, fluid 213 may be directed over first surface 214a and thermal energy transfer element 216 in a controlled manner. While thermal energy transfer assembly 210 has been illustrated in FIG. 6 as including enclosure 222, it should be understood that enclosure 222 may alternatively be omitted, for example, in an arrangement where first surface 214a and thermal energy transfer element 216 are exposed to atmospheric air.

As illustrated in FIGS. 5 and 6, thermal energy transfer element 216 may be a single, continuous pattern, however, it should be understood that thermal energy transfer element 216 may alternatively take the form of a plurality of separate and discrete thermal energy transfer elements which could be associated with respective pedestals 214d and devices 212.

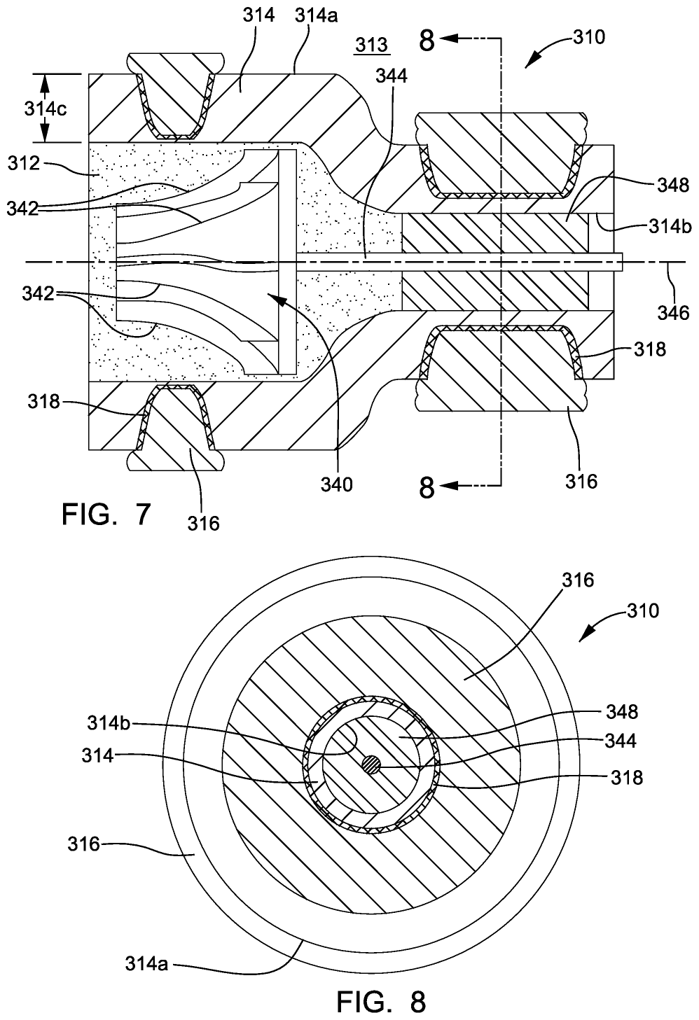

Reference will now be made to FIGS. 7 and 8 where FIG. 7 illustrates an axial cross-sectional view of a thermal energy transfer assembly 310 in the form of a portion of a turbocharger of an internal combustion engine (not shown) and where FIG. 8 illustrates a radial cross-sectional view of thermal energy transfer assembly 310 taken through section line 8-8 of FIG. 7. Thermal energy transfer assembly 310 will be hereinafter referred to as turbocharger 310. It should be noted that FIG. 7 represents only one half of turbocharger 310 and may be either the turbine side or the compressor side of turbocharger 310, however, will hereinafter be described as the turbine side. Turbocharger 310 receives matter 312, herein after referred to as exhaust gases 312, from the internal combustion engine such that exhaust gases 312 are hot from the combustion process. Turbocharger 310 includes a housing 314, i.e. a substrate, which is tubular in nature such that housing 314 includes a first surface 314a on its outer periphery and a second surface 314b on its inner periphery which is separated from first surface 314a such that a thickness 314c is the distance from first surface 314a to second surface 314b in a direction normal to first surface 314a. By way of non-limiting example only, housing 314 is made of aluminum or an aluminum alloy, however, it should be understood that other metals may also be used where the metals may be ferrous or non-ferrous. Turbocharger 310 also includes a turbine 340 having a plurality of blades 342 such that turbine 340 is supported on a shaft 344. Shaft 344 is supported by a bearing 348 which is received within, and fixed to, housing 314 such that turbine 340 and shaft 344 rotate together about an axis 346 when exhaust gases 312 pass through housing 314 and act on blades 342. Shaft 344 in turn rotates a compressor wheel (not shown) which is connected to an end of shaft 344 which is opposite from turbine 340, thereby compressing intake air for the internal combustion engine as would be readily apparent to a practitioner of ordinary skill in the art. Second surface 314b is in thermal conduction with bearing 348 by either direct contact or through an intermediate element.

During operation of turbocharger 310, it may be desirable to provide cooling, i.e. transfer of thermal energy, to exhaust gases 312, housing 314, and bearing 348 by dissipating this heat to a fluid 313 which in this arrangement will be hereinafter referred to as atmosphere 313, i.e. atmospheric air. In order to promote this transfer of thermal energy to atmosphere 313, housing 314 may include one or more thermal energy transfer elements 316 which are made of a second material which is different from the first material of housing 314 such that the second material has a second thermal conductivity coefficient which is greater than the first thermal conductivity coefficient of the first material of housing 314. Preferably, the second thermal conductivity coefficient measured in W/mK is at least 1.5 times the first thermal conductivity coefficient measured in W/mK in order to promote effective thermal energy transfer. By way of non-limiting example only, thermal energy transfer element 316 is made of copper or a copper alloy, however, other materials where the second thermal conductivity coefficient is at least 1.5 times the first thermal conductivity coefficient are also possible. One non-limiting example of a non-metal option for thermal energy transfer elements 316 is graphene, however, other non-metal options may include composite materials. Additionally, thermal energy transfer element 316 may be made of two or more compositions such as copper and silver or gold or alloys thereof. Thermal energy transfer elements 316 are applied to first surface 314a using additive friction stir deposition, as was described previously, such that thermal energy transfer elements 316 extend into housing 314 toward second surface 314b. Each thermal energy transfer element 316 and housing 314 meet together in a stir zone 318 which comprises a mixture of both the first material of housing 314 and the second material of thermal energy transfer element 316. Each thermal energy transfer element 316 not only extends toward second surface 314b, but also extends above first surface 314a. However, it should be understood that each thermal energy transfer element 316 may alternatively not extend above first surface 314a, but rather may be flush with first surface 314a. As illustrated in FIG. 7, one thermal energy transfer element 316 may be aligned with turbine 340 such that it circumferentially surrounds turbine 340 and exhaust gases 312 while another thermal energy transfer element 316 may be aligned with bearing 348 such that it circumferentially surrounds bearing 348. While two thermal energy transfer elements 316 have been illustrated, it should be understood that a greater number or a lesser number may be included based on the thermal energy transfer requirements. As can be most clearly seen in FIG. 8, thermal energy transfer elements 316 may extend continuously around the entire circumference of housing 314 about axis 346 such that they are annular in shape, however, it should be understood that one or more of thermal energy transfer elements may alternatively be segmented around the circumference of housing 314 in order to achieve structural characteristics of housing 314 while also achieving thermal energy transfer requirements. It should be noted that thermal energy transfer element 316 which circumferentially surrounds bearing 348 has been drawn in FIG. 7 to emphasize that it has been created by building up multiple layers as is particularly evident by the scalloped lateral edges which are located outside of housing 314.

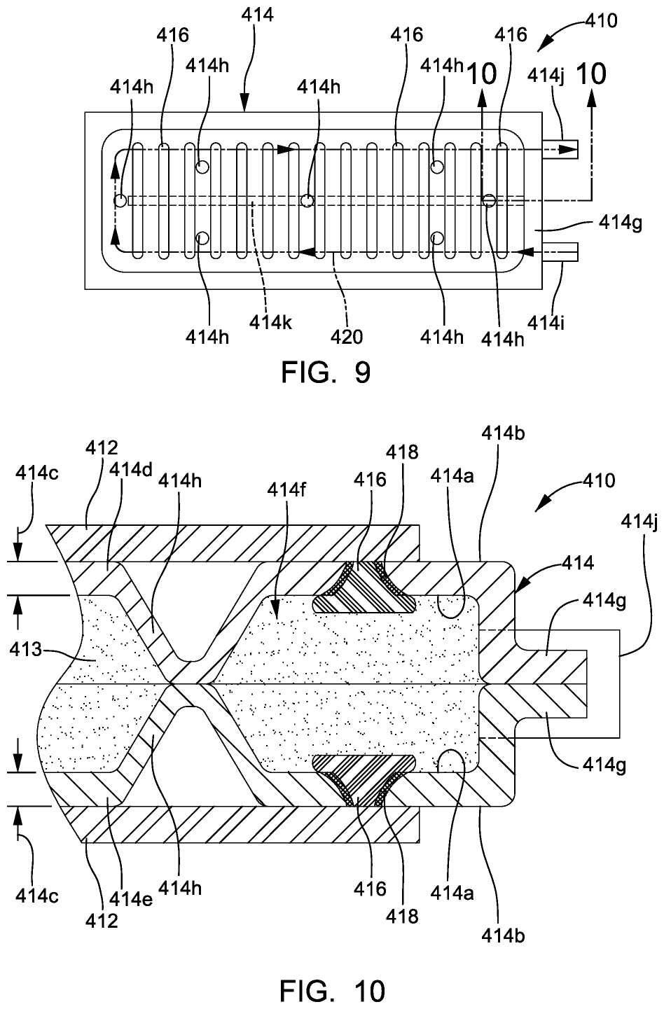

Reference will now be made to FIGS. 9 and 10 where FIG. 9 is an elevation view showing a simplified representation of a thermal energy transfer assembly 410 and FIG. 10 is an enlarged cross-sectional view of a portion of thermal energy transfer assembly 410 taken through section line 10-10 of FIG. 9. Thermal energy transfer assembly 410 is provided for transferring thermal energy between matter 412 and a fluid 413. In other words, thermal energy transfer assembly 410 provides thermal energy to matter 412 or extracts thermal energy from matter 412 based on a thermal energy differential between matter 412 and fluid 413. It should be noted that matter 412 has been omitted from FIG. 9 for clarity. Matter 412 may be, by way of non-limiting example only a device such as an electric motor, a battery such as a battery pack for an electric vehicle, an electronic device such as a power inverter, power converter, power transistor, thyristor, diode, integrated circuit, CPU processor, microprocessor, power handling semiconductor, or LED. Alternatively, matter 412 may be a fluid, e.g. a liquid or a gas to which thermal energy is to be provided or from which thermal energy is to be extracted. Fluid 413 may be a liquid, gas, or phase change material and may be contained within a closed system containing, by way of nonlimiting example only, water or a mixture of water and an antifreeze such as ethylene glycol or propylene glycol which is recirculated or may be an open system such as atmospheric air or water which is not recirculated. Thermal energy transfer assembly 410 includes a substrate 414, hereinafter referred to as housing 414, which is made of a first material having a first thermal conductivity coefficient. As illustrated in FIG. 10, housing 414 may be made from two pieces, namely an upper half 414d and a lower half 414e which are substantially mirror images of each other. Upper half 414d and lower half 414e each have a first surface 414a which are spaced apart from each other and together form a fluid chamber 414f through which fluid 413 passes. Upper half 414d and lower half 414e each also have a second surface 414b which is opposed to, and spaced apart from, first surface 414a by a thickness 414c which is a measure of either upper half 414d between first surface 414a and second surface 414b in a direction normal to first surface 414a or lower half 414e between first surface 414a and second surface 414b in a direction normal to first surface 414a. First surface 414a of each of upper half 414d and lower half 414e are spaced apart from each other by a rim 414g formed at the periphery of each of upper half 414d and lower half 414e such that rim 414g is offset from first surface 414a in a direction normal to first surface 414a. Rim 414g of upper half 414d and rim 414g of lower half 414e are fixed to each other, for example by laser welding or other known means, thereby providing a fluid-tight connection. While rim 414g maintains an offset between first surface 414a of upper half 414d and first surface 414a of lower half 414e at the periphery of housing 414, one or more support pads 414h may be provided on upper half 414d and lower half 414e such that support pads 414h of upper half 414d each mate with a respective one of support pads 414h of lower half 414e where they may be fixed to each other, for example, by laser welding. In this way, support pads 414h maintain offset between first surface 414a of upper half 414d and first surface 414a of lower half 414e within the perimeter of rim 414g. Rim 414g and support pads 414h may be formed through conventional stamping and pressing techniques applied to a sheet of metal. Housing 414 also includes a fluid inlet 414i through which fluid 413 enters housing 414 and a fluid outlet 414j through which fluid exits housing 414. In order to cause fluid to flow across the entirety of first surface 414a when flowing from fluid inlet 414i to fluid outlet 414j, a wall 414k may be provided in housing 414. In this way, fluid 413 flows through housing 414 in a U-shaped path as indicated by flow path 420. Second surface 414b is in thermal conduction with matter 412 by either direct contact or through an intermediate element such as a thermal pad or thermal paste (not shown). By way of non-limiting example only, housing 414 is made of aluminum or an aluminum alloy. While aluminum and aluminum alloy have been given as examples of the material for housing 414, it should be understood that other metals may also be used where the metals may be ferrous or non-ferrous. It should also be understood that the material for housing 414 may alternatively not be a metal, but may be a polymer.

In order to promote transfer of thermal energy between matter 412 and fluid 413 through housing 414, thermal energy transfer assembly 410 also includes one or more thermal energy transfer elements 416 which are made of a second material which is different from the first material of housing 414 such that the second material has a second thermal conductivity coefficient which is greater than the first thermal conductivity coefficient of the first material of housing 414. Preferably, the second thermal conductivity coefficient measured in W/mK is at least 1.5 times the first thermal conductivity coefficient measured in W/mK in order to promote effective thermal energy transfer. By way of non-limiting example only, thermal energy transfer element 416 is made of copper or a copper alloy, however, other materials where the second thermal conductivity coefficient is at least 1.5 times the first thermal conductivity coefficient are also possible. One non-limiting example of a non-metal option for thermal energy transfer elements 416 is graphene, however, other non-metal options may include composite materials. Additionally, thermal energy transfer element 416 may be made of multiple compositions such as copper and silver or gold or alloys thereof. Thermal energy transfer elements 416 are applied to first surface 414a using additive friction stir deposition, as was described previously, such that thermal energy transfer elements 416 extend into housing 414 toward second surface 414b. Each thermal energy transfer element 416 and housing 414 meet together in a stir zone 418 which comprises a mixture of both the first material of housing 414 and the second material of thermal energy transfer element 416. As shown most clearly in FIG. 10, each thermal energy transfer element 416 not only extends toward second surface 414b, but also extends above first surface 414a. However, it should be understood that each thermal energy transfer element 416 may alternatively not extend above first surface 414a, but rather may be flush with first surface 414a. When each thermal energy transfer element 416 extends away from first surface 414a in a direction that is opposite from second surface 414b, the surface area of each thermal energy transfer element 416 that is exposed to fluid 413 is increased, thereby improving thermal energy transfer efficiency. Additionally, each thermal energy transfer element 416 may promote turbulence to the flow of fluid 413 which may be beneficial to thermal energy transfer.

As illustrated in FIG. 9, thermal energy transfer element 416 may be one of a plurality of thermal energy transfer elements 416 (only select thermal energy transfer elements 416 have been labeled as such for clarity) which are each substantially linear and discrete from each other. However, it should be understood that the plurality of thermal energy transfer elements 416 may alternatively be a single, continuous thermal energy transfer element where ends of adjacent parallel sections are joint together in an alternating pattern, thereby forming a serpentine pattern. It is also contemplated that the thermal energy transfer element is not linear, but may take other forms to increase surface area, such as being sinusoidal, square wave or saw tooth in form, or may made in other shapes or patterns which may include an array thermal energy transfer elements where each thermal energy transfer element is a discrete point or post.

The heat transfer assemblies and related methods disclosed herein provide for ease of manufacturing economically while also providing high performance in transferring thermal energy.

While this invention has been described in terms of preferred embodiments thereof, it is not intended to be so limited, but rather only to the extent set forth in the claims that follow.

We claim:

1. A method for forming a thermal energy transfer assembly through which thermal energy is transferred, said method comprising:
providing a substrate made of a first material which has a first thermal conductivity coefficient, said substrate having a first surface and a second surface which is opposed to said first surface; and
applying a thermal energy transfer element, made of a second material having a second thermal conductivity coefficient which is greater than said first thermal conductivity coefficient, to said substrate from said first surface using additive friction stir deposition, such that said thermal energy transfer element extends into said substrate toward said second surface, wherein said thermal energy transfer element and said substrate meet together in a stir zone which comprises a mixture of both said first material and said second material.

2. A method as in claim 1, wherein said thermal energy transfer element extends above said first surface.

3. A method as in claim 1, further comprising placing one of said second surface and said thermal energy transfer element in thermal communication with matter with which thermal energy is transferred.

4. A method as in claim 3, wherein said thermal communication is a thermal conduction arrangement.

5. A method as in claim 3, further comprising:
placing the other of said second surface and said thermal energy transfer element in thermal communication with a fluid which 1) provides thermal energy to said matter through said thermal energy transfer element or 2) extracts thermal energy from said matter through said thermal energy transfer element.

6. A method as in claim 3, wherein said thermal energy transfer element is annular in shape.

7. A method as in claim 6, wherein said thermal energy transfer element circumferentially surrounds said matter.

8. A method as in claim 1, wherein said second thermal conductivity coefficient measured in watts per meter Kelvin (W/mK) is at least 1.5 times said first thermal conductivity coefficient measured in W/mK.

9. A method as in claim 1 wherein said thermal energy transfer element is a first thermal energy transfer element, said method further comprising:
applying a plurality of thermal energy transfer elements made of said second material to said substrate from said first surface using additive friction stir deposition, wherein each of said thermal energy transfer elements extends into said substrate toward said second surface and wherein each of said thermal energy transfer elements and said substrate meet together in a respective stir zone which comprises said mixture of both said first material and said second material.

10. A method as in claim 1, wherein said thermal energy transfer element is flush with said first surface.

11. A thermal energy transfer assembly through which thermal energy is transferred, said thermal energy transfer assembly comprising:
a substrate made of a first material which has a first thermal conductivity coefficient, said substrate having a first surface and a second surface which is opposed to said first surface; and
a thermal energy transfer element made of a second material having a second thermal conductivity coefficient which is greater than said first thermal conductivity coefficient, said thermal energy transfer element is applied to said first surface using additive friction stir deposition and extends into said substrate toward said second surface, wherein said thermal energy transfer element and said substrate meet together in a stir zone which comprises a mixture of both said first material and said second material.

12. A thermal energy transfer assembly as in claim 11, wherein said thermal energy transfer element extends above said first surface.

13. A thermal energy transfer assembly as in claim 11, wherein one of said second surface and said thermal energy transfer element is in thermal communication with matter with which thermal energy is transferred.

14. A thermal energy transfer assembly as in claim 13, wherein said thermal communication is a thermal conduction arrangement.

15. A thermal energy transfer assembly as in claim 13, further comprising:
a fluid passage which contains a fluid in thermal communication with the other of second surface and said thermal energy transfer element such that said fluid 1) provides thermal energy to said matter through said thermal energy transfer element or 2) extracts thermal energy from said matter through said thermal energy transfer element.

16. A thermal energy transfer assembly as in claim 13, wherein said thermal energy transfer element is annular in shape.

17. A thermal energy transfer assembly as in claim 16, wherein said thermal energy transfer element circumferentially surrounds said matter.

18. A thermal energy transfer assembly as in claim 11, wherein said second thermal conductivity coefficient measured in watts per meter Kelvin (W/mK) is at least 1.5 times said first thermal conductivity coefficient measured in W/mK.

19. A thermal energy transfer assembly as in claim 11, wherein said thermal energy transfer element is a first thermal energy transfer element, said thermal energy transfer assembly further comprising:
a plurality of thermal energy transfer elements made of said second material and applied to said first surface using additive friction stir deposition, wherein each of said plurality of thermal energy transfer elements extends into said substrate toward said second surface and wherein each of said thermal energy transfer elements and said substrate meet together in a respective stir zone which comprises said mixture of both said first material and said second material.

20. A thermal energy transfer assembly as in claim 11, wherein said thermal energy transfer element is flush with said first surface.
